(19) United States
(12) Patent Application Publication
(10) Pub. No.: US 2022/0415577 A1
(43) Pub. Date: Dec. 29, 2022

(54) DIELECTRIC MATERIAL AND DEVICE INCLUDING THE SAME

(71) Applicant: Samsung Electronics Co., Ltd., Suwon-si (KR)

(72) Inventors: Taewon JEONG, Yongin-si (KR); Hyeon Cheol PARK, Hwaseong-si (KR); Daejin YANG, Seoul (KR); Doh Won JUNG, Seoul (KR); Giyoung JO, Suwon-si (KR)

(73) Assignee: Samsung Electronics Co., Ltd., Suwon-si (KR)

(21) Appl. No.: 17/521,296

(22) Filed: Nov. 8, 2021

(30) Foreign Application Priority Data
Jun. 29, 2021 (KR) 10-2021-0084768

(51) Int. Cl. H01G 4/12; H01L 49/02

(52) U.S. Cl. CPC H01G 4/1254; H01L 28/55; H01L 27/11507

(57) ABSTRACT

Provided are a dielectric material and a device including the dielectric material. The dielectric material includes (K_{0.5}Na_{0.5})NbO₃ and (K_{0.5}A_{0.5})TiO₃, wherein A is a trivalent element having 3 valence electrons, in a solid solution; and the device includes a plurality of electrodes; and at least one dielectric layer between the plurality of electrodes, wherein the dielectric layers include the dielectric material.

### CROSS-REFERENCE TO RELATED APPLICATION

This application is based on and claims priority under 35 U.S.C. § 119 to Korean Patent Application No. 10-2021-0084768, filed on Jun. 29, 2021, in the Korean Intellectual Property Office, the disclosure of which is incorporated by reference herein in its entirety.

### BACKGROUND

### 1. Field

The present disclosure relates to a dielectric material, and a device including the same.

### 2. Description of the Related Art

The continuously evolving demands for compact and high-capacity electronic devices have brought with them demands for capacitors having smaller sizes and higher capacities than capacitors of the related art. To make sure that smaller-size and higher-capacity capacitors are achievable, dielectric materials that provide further improved dielectric properties are required.

Producing a multi-layered ceramic capacitor (MLCC), which is a small-size and high-capacity type capacitor, requires dielectric layers to be made thinner. This may inevitably cause a rapid increase in the magnitude of the electric field of the device, leading to a decrease in dielectric spontaneous polarization, and thus resulting in a significant drop in permittivity. Accordingly, there is a growing need to replace dielectric materials of the related art with dielectric materials that effectively work in a high electric field region.

### SUMMARY

One aspect provides a dielectric material that has improved structural stability and physical properties and effectively works in a high electric field region.

Another aspect provides an electronic device including the dielectric material.

Additional aspects will be set forth in part in the description, which follows and, in part, will be apparent from the description, or may be learned by practice of the presented embodiments of the disclosure.

According to one aspect, there is provided a dielectric material including (K_{0.5}Na_{0.5})NbO₃ and (K_{0.5}A_{0.5})TiO₃, wherein A is a trivalent element.

The dielectric material may be a solid solution including the (K_{0.5}Na_{0.5})NbO₃ and the (K_{0.5}A_{0.5})TiO₃.

The dielectric material may include a plurality of domains and a polar region in the plurality of domains.

In this case, the plurality of domains include the (K_{0.5}Na_{0.5})NbO₃, and the polar regions include the (K_{0.5}A_{0.5})TiO₃.

In the dielectric material, the (K_{0.5}A_{0.5})TiO₃ may have a molar ratio of about 0.01 to about 0.2 with respect to an entirety of the dielectric material.

The dielectric material may have a permittivity of about 800 to about 1500 in an electric field of about 0 kV/cm to about 87 kV/cm.

The dielectric material may have a rate of change of permittivity (Δε/ε₀) of permittivity (ε₀) in an electric field of 0 kV/cm and permittivity (ε₁) in an electric field of 87 kV/cm represented by Equation (1):

Δε/ε₀=[(ε₁−ε₀)/ε₀]×100% [Equation 1]

An absolute value of the rate of change of permittivity (Δε/ε₀) of the dielectric material may be 40% or less.

The dielectric material may have a temperature coefficient of capacitance (TCC) of about −30% to about 40% at about −55° C. to about 125° C.

The dielectric material may have a composition represented by Formula 1:

(1−x)(K_{0.5}Na_{0.5})NbO₃.x(K_{0.5}A_{0.5})TiO₃ <Formula 1>

In Formula 1, may be 0<x≤0.5. For example, a molar ratio of (K_{0.5}A_{0.5})TiO₃ may have a range where x is 0<x≤0.3.

In the dielectric material, A may be at least one of La, Ce, Pr, Nd, Pm, Sm, Eu, Ga, Tb, Dy, Ho, Er, Tm, Yb, Lu, Sc, Y, Al, In, Ga, or a combination thereof. For example, A may be La, Nd, or Sm.

The dielectric material may be represented by at least one of (1−x)(K_{0.5}Na_{0.5})NbO₃.x(K_{0.5}La_{0.5})TiO₃, (1−x)(K_{0.5}Na_{0.5})NbO₃.x(K_{0.5}Nd_{0.5})TiO₃, or (1−x)(K_{0.5}Na_{0.5})NbO₃.x(K_{0.5}Sm_{0.5})TiO₃, wherein 0<x≤0.2.

The dielectric material may comprise a pseudo-cubic crystal structure.

The dielectric material may have a resistivity of 1.0×10¹¹ Ω·cm or more.

The dielectric material may have a single XRD peak at about 44° to about 48° in an XRD spectrum using Cu Kα radiation.

According to another aspect, there is provided a device including a plurality of electrodes; and at least one dielectric layer between the plurality of electrodes, wherein the dielectric layers include the dielectric material described above.

In the device, the plurality of electrodes may include a plurality of first set of the plurality of electrodes and a second set of the plurality of electrodes, and the first set and the second set may be alternately arranged.

The device may be a multi-layered capacitor.

According to another aspect, there is provided a memory device including a transistor and a capacitor, wherein at least one of the transistor or the capacitor includes the device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a conceptual view for describing the polarization behavior of a ferroelectric thin film of the related art under a high electric field;

FIG. 2 is a conceptual view for describing the polarization behavior of a relaxer-ferroelectric thin film, according to some example embodiments, under a high electric field;

FIG. 3 is a schematic view of a multi-layered ceramic capacitor (MLCC) according to some example embodiments;

FIG. 4 is a flowchart showing a method of synthesizing a relaxer-ferroelectric material according to some example embodiments, process-by-process;

FIG. 5A is an XRD spectrum of an entire angular region of dielectric materials of Examples 1 to 4 and Comparative Example 1, and FIG. 5B is an enlarged view of an XRD peak of a low-angle region (28=44° to 47°) of FIG. 5A;

FIG. 6A is an XRD spectrum of an entire angular region of dielectric materials of Examples 5 to 8 and Comparative Example 1, and FIG. 6B is an enlarged view of an XRD peak of a low-angle region (28=44° to 47°) of FIG. 6A;

FIG. 7A is an XRD spectrum of an entire angular region of dielectric materials of Examples 9 to 11 and Comparative Example 1, and FIG. 7B is an enlarged view of an XRD peak of a low-angle region (28=44° to 47°) of FIG. 7A;

FIG. 8 is a graph showing temperature coefficient of capacitance (TCC) according to temperatures of dielectric materials of Examples 1 to 4 and Comparative Example 1;

FIG. 9 is a graph showing temperature coefficient of capacitance (TCC) according to temperatures of dielectric materials of Examples 5 to 8 and Comparative Example 1;

FIG. 10 is a graph showing temperature coefficient of capacitance (TCC) according to temperatures of dielectric materials of Examples 9 to 11 and Comparative Example 1;

FIG. 11 is a hysteresis loop showing the measurement of polarization behavior according to electric field change of dielectric materials of Examples 1 to 4 and Comparative Example 1;

FIG. 12 is a hysteresis loop of Examples 5 to 8 and Comparative Example 1; and

FIG. 13 is a hysteresis loop of Examples 9 to 11 and Comparative Example 1.

### DETAILED DESCRIPTION

Reference will now be made in detail to some example embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

When the terms “about” or “substantially” are used in this specification in connection with a numerical value, it is intended that the associated numerical value includes a manufacturing tolerance (e.g., ±10%) around the stated numerical value. Moreover, when the words “generally” and “substantially” are used in connection with geometric shapes, it is intended when the terms “about” or “substantially” are used in this specification in connection with a numerical value, it is intended that the associated numerical value includes a manufacturing tolerance (e.g., ±10%) around the stated numerical value. Further, regardless of whether numerical values or shapes are modified as “about” or “substantially,” it will be understood that these values and shapes should be construed as including a manufacturing or operational tolerance (e.g., ±10%) around the stated numerical values or shapes that precision of the geometric shape is not required but that latitude for the shape is within the scope of the disclosure.

Hereinafter, a dielectric material according to some example embodiments, a multi-layered capacitor including the same, and a method of producing the dielectric material will be described in more detail.

### (Dielectric Material)

The dielectric material, according to some example embodiments, has a perovskite structure, and/or includes (K_{0.5}Na_{0.5})NbO₃ and (K_{0.5}A_{0.5})TiO₃. For example, (K_{0.5}Na_{0.5})NbO₃ is a ferroelectric that may have a perovskite structure, and (K_{0.5}A_{0.5})TiO₃ is a dielectric that may have a perovskite structure. (K_{0.5}Na_{0.5})NbO₃ and (K_{0.5}A_{0.5})TiO₃ may form a solid solution. For example, the solid solution may include a base composition and a solid solute, with the base composition including the (K_{0.5}Na_{0.5})NbO₃, and the solid solute including the (K_{0.5}A_{0.5})TiO₃.

The dielectric material may include a plurality of domains and polar regions in the plurality of domains. In some embodiments, the polar regions may have dimensions in the nanometer range, and may be considered polar nano regions. The dielectric material includes polar regions in a plurality of domains, and thus forms a relaxer-ferroelectric. In this case, (K_{0.5}Na_{0.5})NbO₃ forms the domains, and (K_{0.5}A_{0.5})TiO₃ forms the polar regions. For example, the polar regions may be and/or include the solid solute.

In the dielectric material, The dielectric material may be represented by Formula 1.

(1−x)(K_{0.5}Na_{0.5})NbO₃.x(K_{0.5}A_{0.5})TiO₃ <Formula 1>

In Formula 1, A is a trivalent element (e.g., an element having 3 valence electrons), and x may represent a stoichiometric ratio of (K_{0.5}A_{0.5})TiO₃. In some embodiments, x may be 0<x≤0.5, for example 0<x≤0.4, for example 0.01<x≤0.3, and/or for example 0.02<x≤0.2. For example, in some embodiments, (K_{0.5}A_{0.5})TiO₃ may have a molar ratio of about 0.01 to about 0.2.

In some embodiments, A may include, for example, rare earth elements and/or transition metals, but is not limited thereto. Examples of A may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), yttrium (Y), aluminum (Al), indium (In), gallium (Ga), and/or a combination thereof.

For example, A may be at least one of lanthanum (La), neodymium (Nd), and/or samarium (Sm).

Hereinafter, how a dielectric material, according to some example embodiments, works will be described in comparison with how a dielectric material of the related art works.

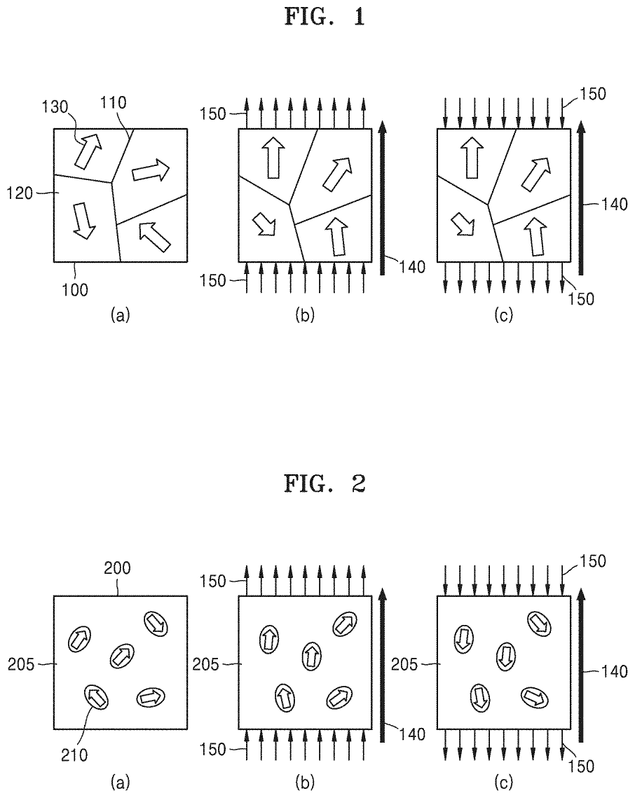

FIG. 1 is a conceptual view for describing the polarization behavior of a ferroelectric thin film of the related art under a high electric field.

In FIG. 1, a ferroelectric material 100, of which the thickness is reduced to several nanometers according to high integration and miniaturization may include KNN, for example, (K_{0.5}Na_{0.5})NbO₃. The ferroelectric material 100 may include domains 120 of KNN separated by boundaries 110. Each domain 120 of the ferroelectric 100 may have a polarization 130. The polarization 130 may be, initially, randomly oriented in each domain 120. For example, when no electric field is applied to the ferroelectric 100, the polarization 130 of each domain 120 is directed in an arbitrary direction as shown in (a) of FIG. 1. A high DC voltage (e.g., a DC bias 140) may be applied to the ferroelectric 100, placing the ferroelectric 100 under a high electric field. Accordingly, the polarization 130 of each domain 120 of the ferroelectric 100 may mostly align in the same direction as the DC bias 140, and thus, as shown in (b) of FIG. 1, the ferroelectric 100 overall exhibits polarization in the same direction as the DC bias 140. Thereafter, as shown in (c) of FIG. 1, even when the direction of an AC bias 150 is changed to the opposite direction to the DC bias 140 under the condition that the DC bias 140 is present in the ferroelectric 100, the direction of the polarization 130 of each domain 120 stays unchanged, and keeps the same direction as the DC bias 140. As such, after the polarization 130 of the ferroelectric 100 is fixed in the DC bias 140 direction, the polarization 130 is fixed without responding to the changes in the AC bias 150.

FIG. 2 is a conceptual view for describing the polarization behavior of a relaxer-ferroelectric thin film, according to some example embodiments, under a high electric field.

Referring to FIG. 2, a relaxer-ferroelectric 200, according to some example embodiments, includes a ferroelectric 205 exhibiting a first polarization characteristic, and polar regions 210 (included in the ferroelectric 205) exhibiting a second polarization characteristic. The first polarization characteristic and the second polarization characteristic may be different from each other. Each of the first polarization characteristic and the second polarization characteristic may include spontaneous polarization characteristics. The relaxer-ferroelectric 200 may be termed as a relaxer-ferroelectric layer. The polar region 210 may be termed as a nano-polar layer and/or a nano-polar portion. The ferroelectric 205 may be termed as a ferroelectric layer.

The polar region 210 may be a region including a solid solute, which may be different from that of the ferroelectric 205. The polar region 210 may be differently termed as a region in which a main element is substituted with another element in a portion of the ferroelectric 205. For example, when the ferroelectric 205 is (K_{0.5}Na_{0.5})NbO₃ (represented by (A)BO), the polar region 210 may be a region formed by defect clusters in which the (K_{0.5}Na_{0.5}) at the A-site of (A)BO is substituted with a first element different from K_{0.5}Na_{0.5}, and/or the Nb at the B-site is substituted with a second element different from Nb. In some embodiments, the first element may be an element serving as a donor, and/or the second element may be an element serving as an acceptor. For example, the first element may be K_{0.5}La_{0.5}, and the second element may be a Ti.

As such, the materials (and/or material composition) of the polar region 210 are different from those of the ferroelectric 205, and thus the first polarization characteristic of the ferroelectric 205 and the second polarization characteristic of the polar region 210 may be different. Accordingly, an energy barrier responding to an AC sweep 150 of the ferroelectric 205 may be different from an energy barrier responding to an AC sweep 150 of the polar region 210. For example, the polar region 210 may have a lower energy barrier responding to the AC sweep 150 than the ferroelectric 205. For that reason, as shown in (b) and (c) of FIG. 2, when the relaxer-ferroelectric 200 is under a high direct current (DC) bias 140, the total polarization of the ferroelectric 205 is fixed in the direction of the DC bias 140 like the ferroelectric 100 in FIG. 1 due to the high electric field caused by the DC bias 140, and thus do not respond to the AC bias 150 applied to the relaxer-ferroelectric 200, but the polarization of the nano polar region 210 responds to the AC bias 150, and thus may have changes in the direction. Therefore, in the relaxer-ferroelectric 200, through solid-solution treatment using a solid solute, it is possible to reduce a fixation phenomenon of a dielectric material under a high electric field and increase permittivity.

In the relaxer-ferroelectric 200 of FIG. 2, the ferroelectric 205 includes a plurality of domains like the ferroelectric 100 of FIG. 1, but which is not illustrated in FIG. 2 for convenience. Each domain included in the ferroelectric 205 may include a plurality of polar regions 210. In each domain, regions other than the polar regions 210 may have different polarization characteristics from the polar regions 210.

The dielectric material according to an embodiment may be, for example, a solid solution represented by the following formulas: (1−x)(K_{0.5}Na_{0.5})NbO₃.x(K_{0.5}La_{0.5})TiO₃, (1−x)(K_{0.5}Na_{0.5})NbO₃.x(K_{0.5}Nd_{0.5})TiO₃, and/or (1−x)(K_{0.5}Na_{0.5})NbO₃.x(K_{0.5}Sm_{0.5})TiO₃. In the formulas, 0<x≤0.2.

The dielectric material containing the composition represented by Formula 1 may have a pseudo-cubic crystal structure. The pseudo-cubic crystal structure is a crystal structure between (e.g., in the process of transiting from) an orthorhombic system to a cubic system, and may refer to a crystal structure similar to the cubic system, in which a ratio of an a-axis to a c-axis of a tetragonal (and/or orthorhombic) system is close to (e.g., about but not equal to) 1.

The dielectric material may have a permittivity of 800 or more in an electric field of about 0 V/μm to about 8.7 V/μm at room temperature (25° C.), and thus a capacitor including such a dielectric material has improved dielectric properties, making it easy to achieve downsizing, thinning, and high capacity. The dielectric material may have a permittivity of 800 or more, for example, about 800 to about 1500, about 800 to about 1200, about 900 to about 1500, and/or about 900 to about 1300.

The dielectric material may have a rate of change of permittivity (Δε/ε₀) between permittivity (ε₀) in an electric field of 0 V/μm and permittivity (ε₁) in an electric field of 8.7 V/μm represented by Equation (1).

Δε/ε₀=[(ε₁−ε₀)/ε₀]×100% [Equation 1]

An absolute value of the rate of change of permittivity (Δε/ε₀) of the dielectric material may be 40% or less. For example, the rate of change of permittivity may be about 20% to 40%. This rate of change of permittivity of the dielectric material may indicate a change in permittivity according to the presence/absence of a direct current (DC) bias.

Meanwhile, temperature coefficient of capacitance (TCC), a numerical value representing the increase/decrease rate of permittivity according to temperature changes, may indicate the temperature stability of permittivity, and may be represented by Equation (2).

TCC={(C−C_{RT})/C_{RT}}×100% [Equation 2]

In Equation (2), C refers to a capacitance value at measurement temperature, and CRT refers to a capacitance value at room temperature of 25° C.

The dielectric material may have a temperature coefficient of capacitance (TCC) of about −30% to about 40% at about −55° C. to about 125° C. This capacitance temperature coefficient of the dielectric material refers to a rate of change of permittivity according to temperature compared to room temperature permittivity.

In addition, the dielectric material may have a resistivity of 1.0×10¹¹ Ω·cm or more, for example, about 1.0×10¹¹ Ω·cm to about 1.0×10¹³ Ω·cm, about 1.0×10¹¹ Ω·cm to about 5.0×10¹² Ω·cm. This resistivity of the dielectric material may refer to the electrical resistivity of a material.

(Device)

A device according to some embodiments may include a plurality of electrodes; and at least one dielectric layer positioned between the plurality of electrodes. The dielectric layer may include the dielectric material according to at least one embodiment described above.

In some embodiments, the device may be and/or include, for example, a capacitor. In addition, the capacitor may include a plurality of internal electrodes; and dielectric layers alternately positioned between the plurality of internal electrodes. For example, the device may be a multi-layered ceramic capacitor (MLCC), as described below.

In some embodiments, the device may be and/or include, for example, a transistor. The dielectric layer may be and/or included in, for example, a gate dielectric layer between, respectively, a source and drain region, and a gate electrode and active region.

The dielectric material may have a resistivity of 1.0×10⁹ Ω·cm or more, for example, 1.0×10¹¹ Ω·cm or more, and/or for example, about 1.2×10¹¹ Ω·cm to about 4.0×10¹¹ Ω·cm. As such, the dielectric layers may be considered to have excellent insulating properties.

For example, the device according to some embodiments includes the dielectric material described above, and thus has improved dielectric properties, thereby having improved electrical properties.

The device may be used in electric circuits, electronic circuits, electromagnetic circuits, and/or the like, but is not particularly limited to these examples and any device that provides electrical outputs with respect to electrical inputs is applicable. The electrical inputs may be current and/or voltage, and the current may be direct current and/or alternating current. The electrical inputs may be continuously input or may be intermittently input according to a predetermined period. The device may store electrical energy, electrical signals, magnetic energy, and/or magnetic signals. The device may be a semiconductor, a memory, a processor, or the like. The device may be and/or include, for example, a resistor, an inductor, a capacitor, a transistor, or the like.

The device may be, for example, a capacitor. The capacitor may be, for example, a stacked capacitor including a plurality of internal electrodes; and the above-described dielectric layers alternately positioned between the plurality of internal electrodes. The capacitor may have an independent device form such as a multi-layered capacitor, but is not necessarily limited to this form, and may be included as a portion of a memory. The capacitor may be, for example, a metal insulator metal (MIM) capacitor mounted in a memory device.

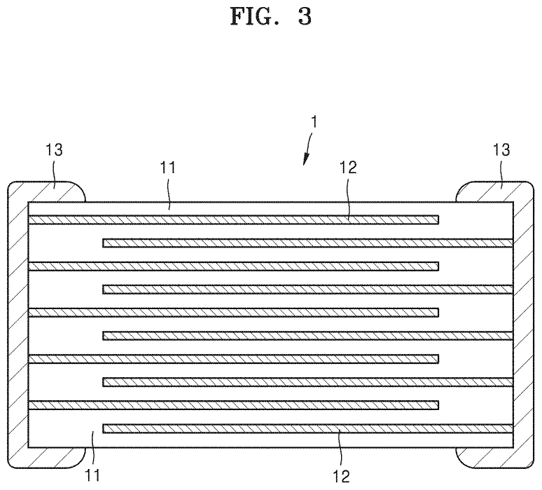

FIG. 3 is a schematic view of a multi-layered ceramic capacitor (MLCC) according to some example embodiments.

Referring to FIG. 3, a multi-layered capacitor 1 according to some example embodiments may include a plurality of internal electrodes 12; and dielectric layers 11 alternately positioned between the plurality of internal electrodes 12. The multi-layered capacitor 1 has a structure in which a plurality of internal electrodes 12 and dielectric layers 11 are alternately stacked, and the dielectric layers 11 include the dielectric material according to at least one embodiment. Adjacent internal electrodes 12 are electrically separated from each other by the dielectric layers 11 positioned therebetween.

In the multi-layered capacitor 1, the internal electrodes 12 and the dielectric layers 11 may be alternately stacked, and thus the dielectric layers 11 positioned between the adjacent internal electrodes 12 and the internal electrodes 12 serve as one unit capacitor. In the multi-layered capacitor 1, the number of the internal electrodes 12 and the dielectric layers 11, which are alternately stacked, is each independently, for example, 2 or more, 5 or more, 10 or more, 20 or more, 50 or more, 100 or more, 200 or more, 500 or more, 1000 or more, 2000 or more, 5000 or more, and/or 10000 or more. The multi-layered capacitor 1 provides capacitance resulting from a structure in which a plurality of internal capacitors are stacked. When the number of the internal electrodes 12 and the dielectric layers 11, which are stacked increases, their contact area increases, thereby improving capacitance.

The internal electrodes 12 may be positioned to have an area smaller than that of the dielectric layers 11, for example. The plurality of internal electrodes 12 may have, for example, the same area, but adjacent internal electrodes 12 may be arranged to be not at the same position along the thickness direction of the multi-layered capacitor 1, but may be arranged to partially protrude in alternating directions from opposite side surfaces of the multi-layered capacitor 1. For example, the plurality of internal electrodes 12 may include a first set of electrodes protruding from a first direction and a second set of electrodes protruding anti-parallel to the first direction. The internal electrodes 12 may be formed using, for example, a conductive paste. For example, the conductive paste may include a metal such as at least one of nickel (Ni), copper (Cu), palladium (Pd), a palladium-silver (Pd—Ag) alloy, and/or the like. Examples of printing methods of the conductive paste may include a screen printing method or a gravure printing method, but are not necessarily limited to these methods, and any method that may be used as a method of forming an internal electrode in the art is applicable. The internal electrodes 12 may have a thickness of, for example, about 100 nm to about 5 μm, about 100 nm to about 2.5 μm, about 100 nm to about 1 μm, about 100 nm to about 800 nm, about 100 nm to about 400 nm, and/or about 100 nm to about 200 nm.

Referring to FIG. 3, the plurality of internal electrodes 12 may be electrically connected to external electrodes 13. The external electrodes 13 may be, for example, arranged in a laminate including a plurality of internal electrodes 12 and the above-described dielectric layers 11 alternately disposed between the plurality of internal electrodes 12, and are connected to the internal electrodes 12. The multi-layered capacitor 1 includes external electrodes 13 respectively connected to the internal electrodes 12. The multi-layered capacitor 1 includes, for example, a pair of external electrodes 13 surrounding both sides of a stack structure formed by the dielectric layer 11 and the internal electrodes 12. For example, the first set of internal electrodes 12 may be electrically connected to an external electrode 13 and the second set of internal electrodes 12 may be connected to another external electrode 13.

The external electrodes 13 may include a material that has electrical conductivity such as metal. The specific material may be determined in consideration of electrical characteristics and structural (and/or chemical) stability. The external electrodes 13 may have, for example, a multi-layered structure. The external electrodes 13 may include, for example, an electrode layer made of Ni in contact with the laminate and the internal electrodes 12, and a plating layer formed on the electrode layer.

Referring to FIG. 3, the dielectric layers 11 of the multi-layered capacitor 1 are disposed to have a larger area than the adjacent internal electrodes 12. In the multi-layered capacitor 1, the dielectric layers 11 disposed between the adjacent internal electrodes 12 may be, for example, connected to each other. The dielectric layers 11 disposed between the adjacent internal electrodes 12 are connected to each other at sides contacting the external electrodes 13 of the multi-layered capacitor 1.

Though an example multi-layered capacitor 1 has been described with reference to FIG. 3, the device including the dielectric material is not so limited. For example, in some examples of the multi-layered capacitor 1 the external electrodes 13 may be omitted. When the external electrodes 13 are omitted, the internal electrodes 12 may protrude towards the sides of the multi-layered capacitor 1 to be connected to a power source.

The thickness of the dielectric layers 11 in an unit capacitor including the adjacent internal electrodes 12 and the dielectric layers 11 disposed therebetween (e.g., the distance between the adjacent internal electrodes 12) may be, for example, about 10 nm to about 1 μm, about 100 nm to about 800 nm, about 100 nm to about 600 nm, and/or about 100 nm to about 300 nm. In the unit capacitor including the adjacent internal electrodes 12 and the dielectric layers 11 disposed therebetween, the dielectric layers 11 have a permittivity of, for example, 1000 or more in the range of about 0 kV/cm to about 90 kV/cm at room temperature (25° C.).

When the multi-layered capacitor 1 includes such dielectric layers 11 (e.g., which are thin in thickness and have a high permittivity) the multi-layered capacitor 1 may have improved capacitance, and reduced thickness and volume. Accordingly, it is possible to provide a small-sized, thin, and high capacity capacitor.

(Method of Producing Dielectric Material)

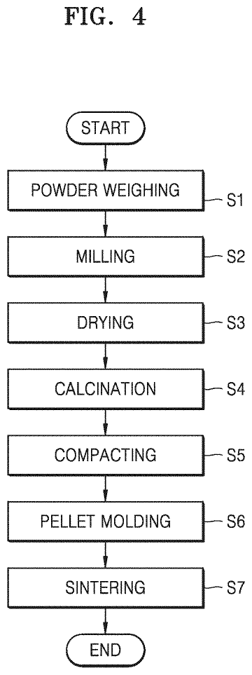

FIG. 4 is a flow chart showing a method of producing a dielectric material according to some example embodiments. FIG. 4 shows an example production process using a solid-phase method.

Referring to FIG. 4, the method of producing a dielectric material including a composition of Formula 1 may include powder weighing (S1), milling (S2), drying (S3), calcination (S4), compacting (S5), CIP (S6), and sintering (S7).

In the powder weighing (S1), a raw material (and/or a precursor) corresponding to a composition of a dielectric material is quantified and weighed according to a molar ratio. The weighing ratio may be determined in consideration of the composition of a target dielectric material. In the powder weighing (S1), in consideration of the composition of Formula 1 (1−x)(K_{0.5}Na_{0.5})NbO₃.x(K_{0.5}A_{0.5})TiO₃, for example, K₂CO₃ may be used as a raw material for K, Na₂CO₃ may be used as a raw material for Na, Nb₂O₅ may be used as a raw material for Nb, Nd₂O₃ may be used as a raw material for Nd, and/or TiO₂ may be used as a raw material for Ti may be used, but the embodiment is not limited thereto. The content of the raw materials described above may be stoichiometrically controlled to obtain the compound of Formula 1.

In the milling (S2), the weighed raw materials are mixed and pulverized. Examples of the milling (S2) may include a ball mill, an airjet mill, a bead mill, a roll mill, a planetary mill, a hand mill, a high energy ball mill, a stirred ball mill, a vibrating mill, and/or a combination thereof. The milling (S2) may be performed using, for example, ball milling. In the milling (S2), the milling may be, for example, wet milling using a solvent. In the wet milling, solvent (such as methanol or ethanol) may be used. In another example, the milling may be dry milling. For example, the milling (S2) may be performed for 24 hours (e.g., through wet milling).

For the wet milling, the resultant subjected to the milling (S2) is dried in the drying (S3). The solvent used in the milling (S2) may be mostly and/or completely removed through the drying (S3). In some embodiments, when the milling (S2) included only drying milling (e.g., did not include a wet willing process) the drying (S3) may be omitted and/or combined with the calcination (S4).

In the calcination (S4), volatile components are removed from the resultant subjected to the drying (S3), thereby increasing the purity of a material. The calcination S4 is a primary heat treatment. Since a great deal of reaction gas is generated near the calcination temperature, the temperature is maintained (e.g., for a certain period of time) to prevent stressing and/or cracking of the material due, e.g., to the reaction gas. The calcination (S4) may be performed at a temperature below the melting point of a target material. Through the calcination (S4), the purity of a ceramic material of a dielectric material may be increased, and a solid-state reaction may also be promoted. In an example, the calcination (S4) may be performed in an air (e.g., ambient) atmosphere at about 800° C. to about 1000° C. for about 10 hours.

In the compacting (S5) and/or pellet molding (S6) the resultant subjected to the calcination (S4) may be molded into a desired form. For example, the resultant may be molded in the form of pellets. In the compacting (S5), an outer form of a dielectric material may be prepared. In the pellet molding (S6), the compacting may further include, e.g., Cold Isostatic Press (CIP). The cold isostatic press may be performed by applying high pressure evenly to a surface of the molded product to compress the resultant. In an example, a pressure of, for example, about 200 MPa may be applied to the molded resultant through cold isostatic press. In some embodiments, the pellet molding (S6) may be included as part of the compacting (S5).

In the sintering (S7) the resultant subjected to the compacting (S5) (and/or pellet molding (S6)) may be baked (e.g., at high temperature). The sintering (S7) may be a secondary heat treatment. The secondary heat treatment may be hotter than the calcination temperature. The temperature of the secondary heat treatment may be selected (and/or otherwise determined) such that the resultant subjected to the compacting (S5) fuse but do not melt. For example, the sintering may be performed at about 1200° C. to about 1500° C. in an air atmosphere for about 5 hours. In some embodiments, pressure may be applied to material during the sintering (S7).

The dielectric material according to an embodiment produced through the processes described above is a high-dielectric material for MLCC having the form of pseudo-cubic and a polar region (PNR) in the trend of downsizing and high capacity devices. In addition, the dielectric material has a dense state with a relative density of 99% or more compared to, for example, a hypothetically ideal dielectric material as described above at room temperature.

The dielectric material, according to some embodiments, is applicable to piezoelectric actuators, as multi-layered dielectric materials for antennas, and as dielectric materials for non-volatile memory devices. In addition, the dielectric material may be implemented in the form of MLCC and/or may be applied to mobile phones, TV sets, parts for vehicles, and/or the like.

### EXAMPLE EMBODIMENTS AND COMPARATIVE EXAMPLES ARE PROVIDED BELOW

### Example 1: Production of Dielectric 0.95(K_{0.5}Na_{0.5})NbO₃-0.05(K_{0.5}Nd_{0.5})TiO₃

A powder including K₂CO₃, Na₂CO₃, Nb₂O₅, Nd₂O₃, and TiO₂ was measured in an amount to obtain the stoichiometry of 0.95(K_{0.5}Na_{0.5})NbO₃-0.05(K_{0.5}Nd_{0.5})TiO₃, and the powder was put into a ball milling device with ethanol and zirconia balls to perform ball milling in an air atmosphere at room temperature for 24 hours, thereby preparing a mixture.

The ball milled mixture was dried at 150° C. for 2 hours to obtain a dry powder. The dry powder was put into an alumina crucible and calcined for 12 hours in an air atmosphere at 950° C. The calcined powder was pressed at uniaxial pressure to mold the powder into pellets, and then the pellets were pressed at a cold isotactic pressure of 250 MPa for 3 minutes to prepare a press-molded product. The press-molded product was sintered in an air atmosphere at 1230° C. for 5 hours to prepare a solid-solutioned dielectric material. The produced dielectric material was found to have a composition of 0.95(K_{0.5}Na_{0.5})NbO₃-0.05(K_{0.5}Nd_{0.5})TiO₃.

### Example 2: Production of Dielectric 0.925(K_{0.5}Na_{0.5})NbO₃-0.075(K_{0.5}Nd_{0.5})TiO₃

A solid-solutioned dielectric was prepared in the same manner as in Example 1, except that an amount of the raw materials included in the powder was controlled such that the produced dielectric material had a composition ratio of 0.925(K_{0.5}Na_{0.5})NbO₃-0.075(K_{0.5}Nd_{0.5})TiO₃.

### Example 3: Production of Dielectric 0.9(K_{0.5}Na_{0.5})NbO₃-0.1(K_{0.5}Nd_{0.5})TiO₃

A solid-solutioned dielectric material was prepared in the same manner as in Example 1, except that an amount of the raw materials included in the powder was controlled such that the produced dielectric material had a composition ratio of 0.9(K_{0.5}Na_{0.5})NbO₃-0.1(K_{0.5}Nd_{0.5})TiO₃.

### Example 4: Production of Dielectric 0.875(K_{0.5}Na_{0.5})NbO₃-0.125(K_{0.5}Nd_{0.5})TiO₃

A solid-solutioned dielectric material was prepared in the same manner as in Example 1, except that an amount of the raw materials included in the powder was controlled such that the produced dielectric material had a composition ratio of 0.875(K_{0.5}Na_{0.5})NbO₃-0.125(K_{0.5}Nd_{0.5})TiO₃.

### Example 5: Production of Dielectric 0.95(K_{0.5}Na_{0.5})NbO₃-0.05(K_{0.5}La_{0.5})TiO₃

A solid-solutioned dielectric material was prepared in the same manner as in Example 1, except that La₂O₃ was used instead of Nd₂O₃. An amount of the raw materials included in the powder was controlled such that the produced dielectric material had a composition ratio of 0.95(K_{0.5}Na_{0.5})NbO₃-0.05(K_{0.5}La_{0.5})TiO₃.

### Example 6: Production of Dielectric 0.925(K_{0.5}Na_{0.5})NbO₃-0.075(K_{0.5}La_{0.5})TiO₃

A solid-solutioned dielectric material was prepared in the same manner as in Example 5, except that an amount of the raw materials included in the powder was controlled such that the produced dielectric material had a composition ratio of 0.925(K_{0.5}Na_{0.5})NbO₃-0.075(K_{0.5}La_{0.5})TiO₃.

### Example 7: Production of Dielectric 0.9(K_{0.5}Na_{0.5})NbO₃-0.1(K_{0.5}La_{0.5})TiO₃

A solid-solutioned dielectric material was prepared in the same manner as in Example 5, except that an amount of the raw material included in the powder was controlled such that the produced dielectric material had a composition ratio of 0.9(K_{0.5}Na_{0.5})NbO₃-0.1(K_{0.5}La_{0.5})TiO₃₃.

### Example 8: Production of Dielectric 0.875(K_{0.5}Na_{0.5})NbO₃-0.125(K_{0.5}La_{0.5})TiO₃

A solid-solutioned dielectric material was prepared in the same manner as in Example 5, except that an amount of the raw materials included in the powder was controlled such that the produced dielectric material had a composition ratio of 0.875(K_{0.5}Na_{0.5})NbO₃-0.125(K_{0.5}La_{0.5})TiO₃.

### Example 9: Production of Dielectric 0.95(K_{0.5}Na_{0.5})NbO₃-0.05(K_{0.5}Sm_{0.5})TiO₃

A solid-solutioned dielectric material was prepared in the same manner as in Example 1, except that Sm₂O₃ was used instead of Nd₂O₃ and an amount of the raw material included in the powder was controlled such that the produced dielectric material had a composition ratio of 0.95(K_{0.5}Na_{0.5})NbO₃-0.05(K_{0.5}Sm_{0.5})TiO₃.

### Example 10: Production of Dielectric 0.925(K_{0.5}Na_{0.5})NbO₃-0.075(K_{0.5}Sm_{0.5})TiO₃

A solid-solutioned dielectric material was prepared in the same manner as in Example 9, except that an amount of the raw material included in the powder was controlled such that the produced dielectric material had a composition ratio of 0.925(K_{0.5}Na_{0.5}))NbO₃-0.075(K_{0.5}Sm_{0.5})TiO₃.

### Example 11: Production of Dielectric 0.9(K_{0.5}Na_{0.5}))NbO₃-0.1(K_{0.5}Sm_{0.5})TiO₃

A solid-solutioned dielectric material was prepared in the same manner as in Example 9, except that an amount of the raw material included in the powder was controlled such that the produced dielectric material had a composition ratio of 0.9(K_{0.5}Na_{0.5}))NbO₃-0.1(K_{0.5}Sm_{0.5})TiO₃.

### Comparative Example 1: Production of Dielectric KNN

A solid-solutioned dielectric material was prepared in the same manner as in Example 1, except that the powder included K₂CO₃, Na₂CO₃, and Nb₂O₅ as raw material. An amount of the raw material included in the powder was controlled such that the produced dielectric material had a composition ratio of (K_{0.5}Na_{0.5})NbO₃.

FIG. 1 shows the solid solution compositions of the dielectric materials of Examples 1 to 11 and Comparative Example 1.

TABLE 1

| Item | Solid solution composition | Abbreviation |
|---|---|---|
| Comparative | (K_{0.5}Na_{0.5})NbO₃ | KNN |
| Example 1 | | |
| Example 1 | 0.950(K_{0.5}Na_{0.5})NbO₃—0.050(K_{0.5}Nd_{0.5})TiO₃ | 0.950KNN-0.050KNT |
| Example 2 | 0.925(K_{0.5}Na_{0.5})NbO₃—0.075(K_{0.5}Nd_{0.5})TiO₃ | 0.925KNN-0.075KNT |
| Example 3 | 0.900(K_{0.5}Na_{0.5})NbO₃—0.100(K_{0.5}Nd_{0.5})TiO₃ | 0.900KNN-0.100KNT |
| Example 4 | 0.875(K_{0.5}Na_{0.5})NbO₃—0.125(K_{0.5}Nd_{0.5})TiO₃ | 0.875KNN-0.125KNT |
| Example 5 | 0.950(K_{0.5}Na_{0.5})NbO₃—0.050(K_{0.5}La_{0.5})TiO₃ | 0.950KNN-0.050KLT |
| Example 6 | 0.925(K_{0.5}Na_{0.5})NbO₃—0.075(K_{0.5}La_{0.5})TiO₃ | 0.925KNN-0.075KLT |
| Example 7 | 0.900(K_{0.5}Na_{0.5})NbO₃—0.100(K_{0.5}La_{0.5})TiO₃ | 0.900KNN-0.100KLT |
| Example 8 | 0.875(K_{0.5}Na_{0.5})NbO₃—0.125(K_{0.5}La_{0.5})TiO₃ | 0.875KNN-0.125KLT |
| Example 9 | 0.950(K_{0.5}Na_{0.5})NbO₃—0.050(K_{0.5}Sm_{0.5})TiO₃ | 0.950KNN-0.050KST |
| Example 10 | 0.925(K_{0.5}Na_{0.5})NbO₃—0.075(K_{0.5}Sm_{0.5})TiO₃ | 0.925KNN-0.075KST |
| Example 11 | 0.900(K_{0.5}Na_{0.5})NbO₃—0.100(K_{0.5}Sm_{0.5})TiO₃ | 0.900KNN-0.100KST |

Crystal Structure

For the dielectric materials produced in Examples and Comparative Examples, x-ray diffraction (XRD) spectra were measured using Cu Kα radiation. Each dielectric material was measured in pellet bulk form.

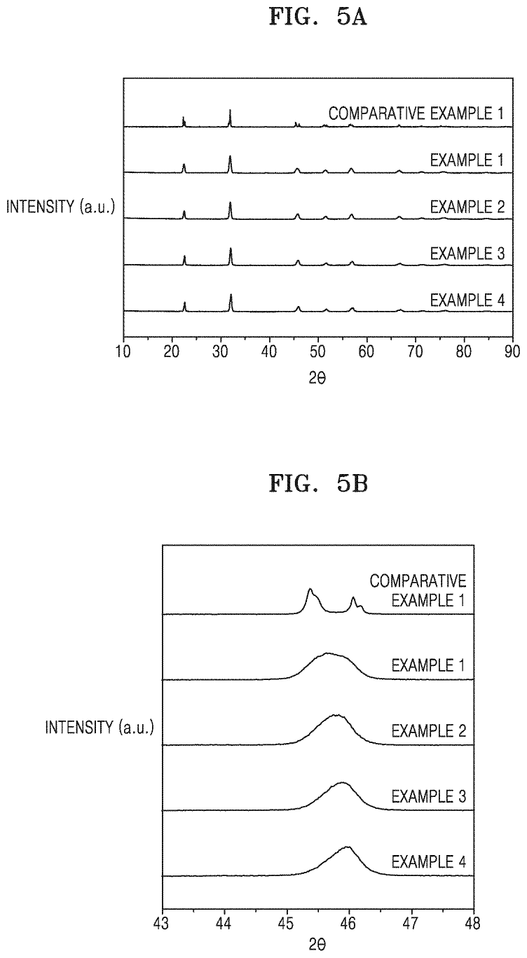

FIG. 5A is an XRD spectrum of an entire angular region of dielectric materials of Examples 1 to 4 and Comparative Example 1, and FIG. 5B is an enlarged view of an XRD peak of a low-angle region (28=44° to 47°) of FIG. 5A.

Referring to FIG. 5A, the XRD patterns of the dielectric materials of Examples 1 to 4 and the XRD pattern of the dielectric material of Comparative Example 1 are mostly consistent. The results indicate that the dielectric materials of Examples 1 to 4 (e.g., in which (K_{0.5}Nd_{0.5})TiO₃ was solid-solutioned in (K_{0.5}Na_{0.5})NbO₃) have the same single phase as (K_{0.5}Na_{0.5})NbO₃.

Referring to FIG. 5B, in the (K_{0.5}Na_{0.5})NbO₃ dielectric material of Comparative Example 1, two peaks corresponding to crystal planes (022) and (200) are observed between 45° and 46.5°, which indicates that the peaks have an orthorhombic crystal structure. On the other hand, in the dielectric materials of Examples 1 to 4, only one broad peak is observed between 45° and 46.5°. This indicates that the crystal structure of the dielectric materials was pseudo-cubic when (K_{0.5}Nd_{0.5})TiO₃ was solid-solutioned in (K_{0.5}Na_{0.5})NbO₃. The pseudo-cubic indicates that the ratio of an a-axis to a c-axis of the crystal got closer to 1, resulting in a crystal similar to a cubic system. Meanwhile, it is shown that in the dielectric materials of Examples 1 to 4, when a molar ratio of (K_{0.5}Nd_{0.5})TiO₃ increased, the width of the peak between 45° and 46.5° became smaller, and that suggests that the increase in solid solution concentration caused greater pseudo-cubic.

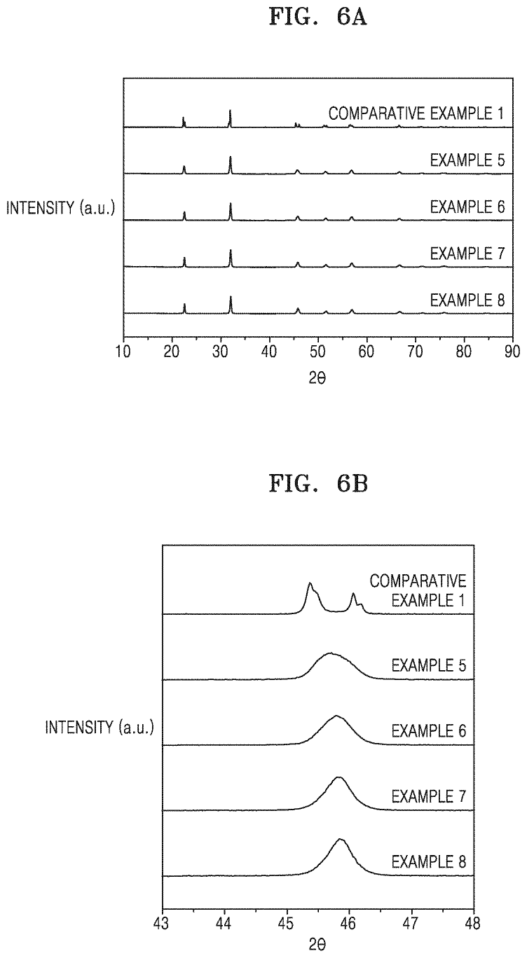

FIG. 6A is an XRD spectrum of an entire angular region of dielectric materials of Examples 5 to 8 and Comparative Example 1, and FIG. 6B is an enlarged view of an XRD peak of a low-angle region (28=44° to 47°) of FIG. 6A.

Referring to FIG. 6A, the XRD patterns of the dielectric materials of Examples 5 to 8 and the XRD pattern of the dielectric material of Comparative Example 1 are mostly consistent. The results indicate that the dielectric materials of Examples 5 to 8 in which (K_{0.5}La_{0.5})TiO₃ was solid-solutioned in (K_{0.5}Na_{0.5})NbO₃ have the same single phase as (K_{0.5}Na_{0.5})NbO₃.

Referring to FIG. 6B, only one broad peak is observed between 45° and 46.5° in the dielectric materials of Examples 5 to 8 (e.g., as in the dielectric materials of Examples 1 to 4). This indicates that the crystal structure of the dielectric materials was pseudo-cubic when (K_{0.5}La_{0.5})TiO₃ was solid-solutioned in (K_{0.5}Na_{0.5})NbO₃. Meanwhile, it is shown that in the dielectric materials of Examples 5 to 8, when a molar ratio of (K_{0.5}La_{0.5})TiO₃ increased, the width of the peak between 45° and 46.5° became smaller, and that suggests that the increase in solid solution concentration caused greater conversion into pseudo-cubic.

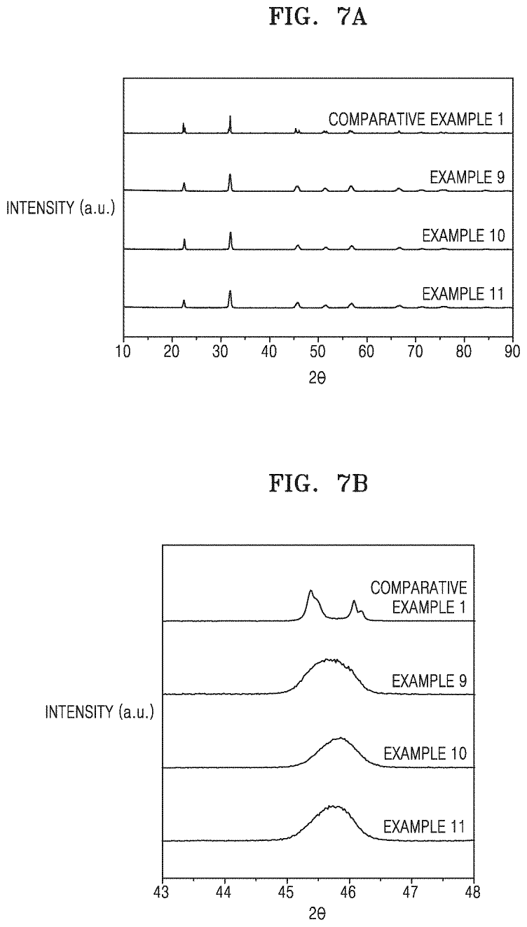

FIG. 7A is an XRD spectrum of an entire angular region of dielectric materials of Examples 9 to 11 and Comparative Example 1, and FIG. 7B is an enlarged view of an XRD peak of a low-angle region (28=44° to 47°) of FIG. 7A.

Referring to FIG. 7A, the XRD patterns of the dielectric materials of Examples 9 to 11 and the XRD pattern of the dielectric material of Comparative Example 1 are mostly consistent. The results indicate that the dielectric materials of Examples 5 to 8 in which (K_{0.5}Sm_{0.5})TiO₃ was solid-solutioned in (K_{0.5}Na_{0.5})NbO₃ have the same single phase as (K_{0.5}Na_{0.5})NbO₃.

Referring to FIG. 7B, only one broad peak is observed between 45° and 46.5° in the dielectric materials of Examples 9 to 11 (e.g., as in the dielectric materials of Examples 1 to 4). This indicates that the crystal structure of the dielectric materials was pseudo-cubic when (K_{0.5}Sm_{0.5})TiO₃ was solid-solutioned in (K_{0.5}Na_{0.5})NbO₃. Meanwhile, it is shown that in the dielectric materials of Examples 9 to 11, when a molar ratio of (K_{0.5}Sm_{0.5})TiO₃ increased, the width of the peak between 45° and 46.5° became smaller, and that suggests that the increase in solid solution concentration caused greater pseudo-cubic.

Temperature Coefficient of Capacitance

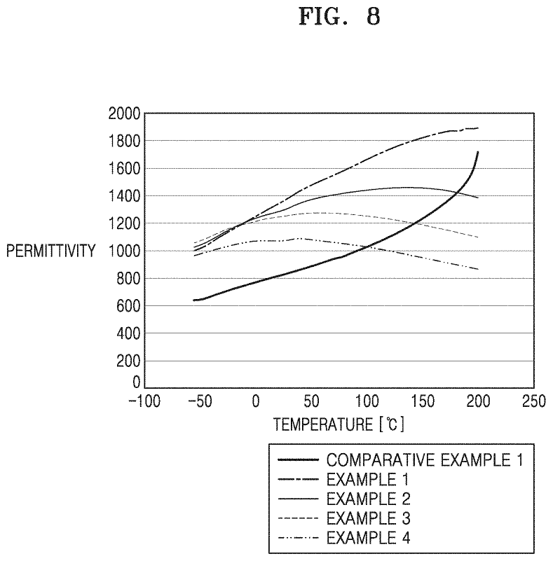

FIG. 8 is a graph showing temperature coefficient of capacitance (TCC) according to temperatures of dielectric materials of Examples 1 to 4 and Comparative Example 1.

As indicated above, the temperature coefficient of capacitance (TCC) is a numerical value representing the increase/decrease rate of permittivity according to temperature changes to indicate temperature stability of permittivity, and is represented by Equation (2).

Referring to FIG. 8, the (K_{0.5}Na_{0.5})NbO₃ dielectric material of Comparative Example 1 has a lower permittivity than the dielectric materials of Examples 1 to 4 at 100° C. or less. In addition, in FIG. 8, the dielectric material of Comparative Example 1 has a continuously increasing permittivity value as the temperature increases. This indicates that the (K_{0.5}Na_{0.5})NbO₃ dielectric material of Comparative Example 1 is temperature-dependent. Without being limited to a particular theory, in the (K_{0.5}Na_{0.5})NbO₃ dielectric material of Comparative Example 1 the dielectric transitions from an orthorhombic structure (exhibiting a ferroelectric) to a tetragonal structure at about 200° C., and transitions from the tetragonal structure to a cubic structure (exhibiting a paraelectric) at 400° C., and has a rapidly increasing permittivity at each transition point.

Meanwhile, the dielectric materials of Examples 1 to 4, which are solid solutions of (K_{0.5}Na_{0.5})NbO₃ and (K_{0.5}Nd_{0.5})TiO₃, exhibit a permittivity of 900 or more (and/or 1000 or more) at 100° C. or less. In addition, it is shown that the temperature at which the maximum permittivity is observed decreases to, respectively, around 200° C., 130° C., 60° C., and 35° C. when the molar ratio of (K_{0.5}Nd_{0.5})TiO₃ increases. Without being limited to a particular theory, the dielectric materials of Examples 1 to 4 exhibit a high permittivity at room temperature because the transition temperature for the pseudo-cubic phase is lowered due to solid solution treatment. In addition, it is considered that the pseudo-cubic occurred at a lower temperature when the solid solution concentration of (K_{0.5}Nd_{0.5})TiO₃ increased.

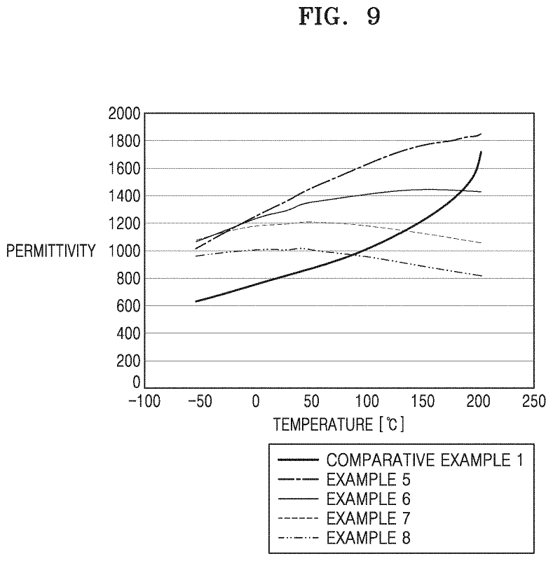

FIG. 9 is a graph showing temperature coefficient of capacitance (TCC) according to temperatures of dielectric materials of Examples 5 to 8 and Comparative Example 1. The dielectric materials of Examples 5 to 8, which are solid solutions of (K_{0.5}Na_{0.5})NbO₃ and (K_{0.5}La_{0.5})TiO₃, exhibit a permittivity of 900 or more (and/or 1000 or more) at 100° C. or less like the dielectric materials of Examples 1 to 4, and it is shown that the temperature at which the maximum permittivity is observed decreases, respectively, to around 200° C., 190° C., 40° C., and 35° C. when the molar ratio of (K_{0.5}La_{0.5})TiO₃ increases.

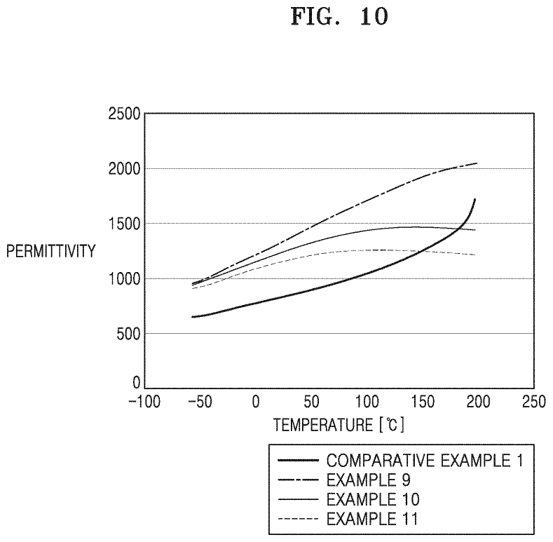

FIG. 10 is a graph showing temperature coefficient of capacitance (TCC) according to temperatures of dielectric materials of Examples 9 to 11 and Comparative Example 1. The dielectric materials of Examples 9 to 11, which are solid solutions of (K_{0.5}Na_{0.5})NbO₃ and (K_{0.5}Sm_{0.5})TiO₃, exhibit a permittivity of 900 (and/or more or 1000) or more at 100° C. or less like the dielectric materials of Examples 1 to 4, and it is shown that the temperature at which the maximum permittivity is observed decreases, respectively, to around 200° C., 140° C., and 125° C. when the molar ratio of (K_{0.5}Sm_{0.5})TiO₃ increases.

Polarization Behavior

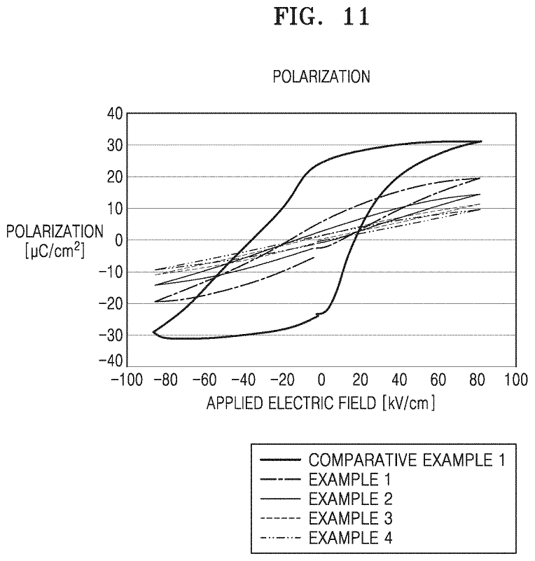

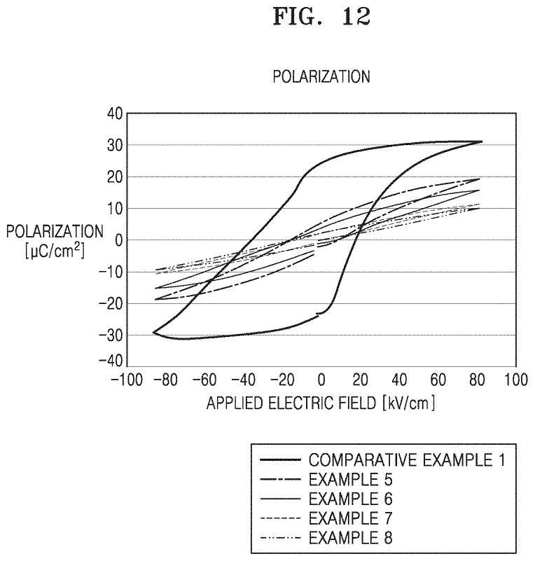

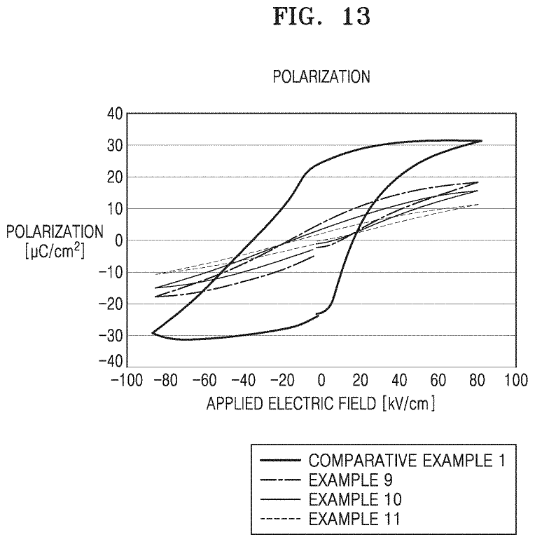

FIG. 11 is a hysteresis loop showing the measurement of polarization behavior according to electric field change of dielectric materials of Examples 1 to 4 and Comparative Example 1, FIG. 12 is a hysteresis loop of Examples 5 to 8 and Comparative Example 1, and FIG. 13 is a hysteresis loop of Examples 9 to 11 and Comparative Example 1. Referring to FIGS. 11 to 13, the KNN dielectric material of Comparative Example 1 shows a typical hysteresis loop of a ferroelectric, whereas the dielectric materials of Examples 1 to 11 show a hysteresis loop close to a paraelectric. The polarization behavior of the dielectric materials of Examples 1 to 11 as such is considered to be caused due to pseudo-cubic from the tetragonal system to the cubic system as the solid-solutioning occurred. Meanwhile, in the dielectric materials of Examples 1 to 11, when the solid solution concentration increases, the hysteresis loop becomes flatter, showing a hysteresis loop closer to a paraelectric; thus, it may be considered that a greater amount and/or conversion of the pseudo-cubic occurred with an increase in the solid solution concentration.

Tables 2 and 3 show the particle size (e.g., grain size), density, nominal permittivity, resistivity, permittivity (ε₀, ε) and rate of change of permittivity (Δε/ε0) at electric fields of 0 V/μm and 8.7 V/μm, and temperature coefficient of capacitance for Examples 1 to 11 and Comparative Example 1.

The nominal permittivity (εᵣ) is permittivity measured when silver (Ag) is applied to both sides of a dielectric pellet to form an electrode, and against the frequency range of AC 1V, 1 kHz at room temperature (25° C.) using E4980A Precision LCR Meter (Keysight), and tanδ represents a loss rate. Resistivity is a value measured for 1 second after stabilization for 60 seconds in a DC application condition of a high electric field (8.7 V/μm) using Premier II Ferroelectric Tester (Radiant Technologies, Inc.). In the rate of change of permittivity, Δε is Δε=ε−ε₀. The temperature coefficient of capacitance (TCC) was measured at a temperature of about −55° C. to about 200° C.

TABLE 2

| | | Particle | | Nominal | | |
|---|---|---|---|---|---|---|
| | | size | | permittivity | | Resistivity |
| | Composition ratio | (μm) | Density | εᵣ | Tanδ | (Ω · cm) |
| Comparative | KNN | 1.5 | 99% | 608 | 0.03 | 2.1E+05 |
| Example 1 | | | | | | |
| Example 1 | 0.950KNN-0.050KNT | 0.27 | 99% | 1135 | 0.04 | 1.7E+11 |
| Example 2 | 0.925KNN-0.075KNT | 0.23 | 100% | 1252 | 0.02 | 1.0E+12 |
| Example 3 | 0.900KNN-0.100KNT | 0.20 | 100% | 1169 | 0.03 | 1.3E+12 |
| Example 4 | 0.875KNN-0.125KNT | 0.19 | 100% | 1001 | 0.03 | 3.1E+11 |
| Example 5 | 0.950KNN-0.050KLT | 0.26 | 100% | 1223 | 0.03 | 6.6E+11 |
| Example 6 | 0.925KNN-0.075KLT | 0.21 | 100% | 1180 | 0.03 | 1.5E+12 |
| Example 7 | 0.900KNN-0.100KLT | 0.18 | 100% | 1106 | 0.02 | 7.3E+11 |
| Example 8 | 0.875KNN-0.125KLT | 0.18 | 100% | 946 | 0.04 | 3.1E+11 |
| Example 9 | 0.950KNN-0.050KST | 0.26 | 100% | 1201 | 0.03 | 3.3E+11 |
| Example 10 | 0.925KNN-0.075KST | 0.22 | 100% | 1210 | 0.03 | 1.0E+11 |
| Example 11 | 0.900KNN-0.100KST | 0.21 | 100% | 1070 | 0.03 | 3.0E+11 |

TABLE 3

| | | ε₀ | ε | | |
|---|---|---|---|---|---|
| | Composition ratio | (@0 V/μm) | (@8.7 V/μm) | (Δε/ε₀) × 100 | TCC |
| Comparative | KNN | 867 | 350 | −60% | −22~37 |
| Example 1 | | | | | |
| Example 1 | 0.950KNN-0.050KNT | 1444 | 902 | −38% | −27~29 |
| Example 2 | 0.925KNN-0.075KNT | 1473 | 1041 | −29% | −21~12 |
| Example 3 | 0.900KNN-0.100KNT | 1250 | 955 | −24% | −15~2 |
| Example 4 | 0.875KNN-0.125KNT | 1099 | 903 | −18% | −10~1 |
| Example 5 | 0.950KNN-0.050KLT | 1375 | 862 | −37% | −25~26 |
| Example 6 | 0.925KNN-0.075KLT | 1380 | 1010 | −27% | −18~11 |
| Example 7 | 0.900KNN-0.100KLT | 1220 | 939 | −23% | −10~1 |
| Example 8 | 0.875KNN-0.125KLT | 1065 | 873 | −18% | −9~1 |
| Example 9 | 0.950KNN-0.050KST | 1327 | 833 | −37% | −28~37 |
| Example 10 | 0.925KNN-0.075KST | 1337 | 934 | −30% | −24~19 |
| Example 11 | 0.900KNN-0.100KST | 1144 | 833 | −27% | −21~10 |

Referring to Table 2, it is shown that the dielectrics of Examples 1 to 11 were made of particles having a diameter of 0.18 μm or more, and had a density of 99% to 100%, where at a density of 100% there were no voids present. The dielectrics of Examples 1 to 11 have a nominal permittivity (εᵣ) of 900 or more, and a resistivity of 1.0E+11 ohm*cm or more, indicating high dielectric properties.

Table 3 shows a permittivity (ε₀) of 1000 or more in a non-electric field (at 0V/μm), a high permittivity (ε) of 700 or more in a high electric field (at 8.7V/μm), and the rate of change of permittivity ((Δε/ε₀)×100) having a value of about 20% to 40% as an absolute value. In addition, it was observed that the temperature coefficient of capacitance (TCC) was −28% to 37%, in particular, Examples 2 to 4 and Examples 6 to 8 and Example 11 showed a temperature coefficient of capacitance (TCC) of −22% to 22% in all temperature ranges, exhibiting stable permittivity temperature characteristics.

Although an embodiment of the present disclosure has been described with reference to drawings and examples, this is only for illustrative purposes, and therefore, those skilled in the art will appreciate that various modifications and other equivalent embodiments may be made therein. Hence, the protective scope of the present disclosure shall be determined by the scope of the appended claims.

Provided is a dielectric material that has a polar region in a domain, and thus have improved structural stability and physical properties and effectively works in a high electric field region.

The dielectric works effectively in a high electric field region, and thus a highly efficient capacitor obtained by thinning dielectric layers, and a device including the same may be produced.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A dielectric material comprising:
(K_{0.5}Na_{0.5})NbO₃; and
(K_{0.5}A_{0.5})TiO₃,
wherein A is a trivalent element.

2. The dielectric material of claim 1, wherein the dielectric material is a solid solution including the (K_{0.5}Na_{0.5})NbO₃ and the (K_{0.5}A_{0.5})TiO₃.

3. The dielectric material of claim 1, wherein the dielectric material comprises:
a plurality of domains; and
polar regions in the plurality of domains.

4. The dielectric material of claim 3, wherein
the plurality of domains include the (K_{0.5}Na_{0.5})NbO₃, and
the polar regions include the (K_{0.5}A_{0.5})TiO₃.

5. The dielectric material of claim 1, wherein the (K_{0.5}A_{0.5})TiO₃ has a molar ratio of about 0.01 to about 0.2 with respect to an entirety of the dielectric material.

6. The dielectric material of claim 1, wherein the dielectric material has a composition represented by Formula 1:
(1−x)(K_{0.5}Na_{0.5})NbO₃.x(K_{0.5}A_{0.5})TiO₃ <Formula 1>
wherein, in Formula 1, 0<x≤0.5.

7. The dielectric material of claim 6, wherein 0<x≤0.3.

8. The dielectric material of claim 1, wherein A is at least one of La, Ce, Pr, Nd, Pm, Sm, Eu, Tb, Dy, Ho, Er, Tm, Yb, Lu, Sc, Y, Al, In, or Ga.

9. The dielectric material of claim 8, wherein A is at least one of La, Nd, or Sm.

10. The dielectric material of claim 1, wherein
the dielectric material is represented by at least one of (1−x)(K_{0.5}Na_{0.5})NbO₃.x(K_{0.5}La_{0.5})TiO₃, (1−x)(K_{0.5}Na_{0.5})NbO₃.x(K_{0.5}Nd_{0.5})TiO₃, or (1−x)(K_{0.5}Na_{0.5})NbO₃.x(K_{0.5}Sm_{0.5})TiO₃, and
0<x≤0.2.

11. The dielectric material of claim 1, wherein the dielectric material has a permittivity of about 800 to about 1500 in an electric field of about 0 kV/cm to about 87 kV/cm.

12. The dielectric material of claim 1,
wherein the dielectric material has a rate of change of permittivity (Δε/ε₀) of permittivity (ε₀) in an electric field of 0 kV/cm and permittivity (ε₁) in an electric field of 87 kV/cm represented by Equation (1):
Δε/ε₀=[(ε₁−ε₀)/ε₀]×100% [Equation 1]
wherein an absolute value of the rate of change of permittivity (Δε/ε₀) is 40% or less.

13. The dielectric material of claim 1, wherein the dielectric material has a temperature coefficient of capacitance (TCC) of about −30% to about 40% at about −55° C. to about 125° C.

14. The dielectric material of claim 1, wherein the dielectric material comprises a pseudo-cubic crystal structure.

15. The dielectric material of claim 1, wherein the dielectric material has a resistivity of 1.0×10¹¹ Ω·cm or more.

16. The dielectric material of claim 1, wherein the dielectric material has a single XRD peak at about 44° to about 48° in an XRD spectrum using Cu Kα radiation.

17. A device comprising:
a plurality of electrodes; and
at least one dielectric layer between the plurality of electrodes,
wherein the at least one dielectric layer includes (K_{0.5}Na_{0.5})NbO₃ and (K_{0.5}A_{0.5})TiO₃, and A is a trivalent element.

18. The device of claim 17, wherein the plurality of electrodes comprise:
a first set of the plurality of electrodes, and
a second set of the plurality of electrodes, and
wherein the first set and the set alternate.

19. The device of claim 17,
wherein the device is a multi-layered capacitor.

20. A memory device comprising a transistor and a capacitor,
wherein at least one of the transistor or the capacitor includes the device of claim 17.
